(19) United States
(12) Patent Application Publication
(10) Pub. No.: US 2025/0113563 A1
(43) Pub. Date: Apr. 3, 2025

(54) STACKED NANOWIRE TRANSISTOR STRUCTURES WITH ISOLATION REGIONS BOUND BY GATE CUTS

(71) Applicant: Intel Corporation, Santa Clara, CA (US)

(72) Inventors: Leonard Guler, Hillsboro, OR (US); Saurabh Acharya, Beaverton, OR (US); Nidhi Khandelwal, Portland, OR (US); Prabhjot Kaur Luthra, Hillsboro, OR (US); Sean Pursel, Tigard, OR (US); Izabela Anna Samek, Hillsboro, OR (US)

(73) Assignee: Intel Corporation, Santa Clara, CA (US)

(21) Appl. No.: 18/478,545

(22) Filed: Sep. 29, 2023

(51) Int. Cl. H01L 29/06; H01L 27/088; H01L 29/417; H01L 29/423; H01L 29/78

(52) U.S. Cl. CPC H10D 62/119; H10D 30/62; H10D 30/6219; H10D 30/6735; H10D 62/116; H10D 84/834

(57) ABSTRACT

In one embodiment, an integrated circuit structure includes a first transistor device comprising a first gate stack and a second transistor device comprising a second gate stack. The second transistor device is spaced a first distance laterally from the first transistor device. The structure further includes a dielectric region between the first gate stack and the second gate stack. The dielectric region is spaced a second distance laterally from the first transistor device, where the first distance is substantially twice the second distance.

### BACKGROUND

In the manufacture of integrated circuit devices, multi-gate transistors, such as tri-gate transistors, have become more prevalent as device dimensions continue to scale down. In conventional processes, tri-gate transistors are generally fabricated on either bulk silicon substrates or silicon-on-insulator substrates. In some instances, bulk silicon substrates are preferred due to their lower cost and because they enable a less complicated tri-gate fabrication process. In another aspect, maintaining mobility improvement and short channel control as microelectronic device dimensions scale below the 10 nanometer (nm) node provides a challenge in device fabrication. Nanowires used to fabricate devices provide improved short channel control.

Scaling multi-gate and nanowire transistors has not been without consequence, however. As the dimensions of these fundamental building blocks of microelectronic circuitry are reduced and as the sheer number of fundamental building blocks fabricated in a given region is increased, the constraints on the lithographic processes used to pattern these building blocks have become overwhelming. In particular, there may be a trade-off between the smallest dimension of a feature patterned in a semiconductor stack (the critical dimension) and the spacing between such features.

### BRIEF DESCRIPTION OF THE DRAWINGS

FIGS. 1A-1D illustrate a perspective view of an example process for fabricating nanowire transistor structures with isolation regions in accordance with embodiments herein.

FIGS. 2A-2B illustrate side cross-sectional views of the structure of FIGS. 1A-1D after an isolation region has been formed.

FIGS. 3A-3B illustrate the example structure shown in FIGS. 2A-2B in the scenario in which an opening in a photoresist layer is misaligned.

FIG. 4 illustrates a flow diagram of an example process for fabricating isolation regions in a structure comprising multiple transistor devices separated by gate cut plug regions.

FIG. 5 is a top view of a wafer and dies that may incorporate any of the embodiments disclosed herein.

FIG. 6 is a cross-sectional side view of an integrated circuit device that may incorporate any of the embodiments disclosed herein.

FIGS. 7A-D are perspective views of example planar, FinFET, gate-all-around, and stacked gate-all-around transistors.

FIG. 8 is a cross-sectional side view of an integrated circuit device assembly that may include any of the embodiments disclosed herein.

FIG. 9 is a block diagram of an example electrical device that may include any of the embodiments disclosed herein.

### DETAILED DESCRIPTION

One or more embodiments described herein are directed to integrated circuit structures having fin isolation regions formed after metal gate processing, which may be referred to as post replacement gate fin trim isolation (FTI). One or more embodiments described herein are directed to gate-all-around devices with fin isolation regions bound by gate cuts. It is to be appreciated that, unless indicated otherwise, reference to nanowires herein can indicate nanowires, nanoribbons, nanosheets, or any suitable gate all around (GAA) transistor technology. In addition, aspects of the present disclosure can be applied to FinFET transistor technologies as well.

To provide context, a fin trim isolation (FTI) process is becoming very complex as the gate pitch and fin (or wire stack) pitch is shrinking. A standard FTI process involves fabrication of a plug in the gate and underlying channel structures. The plug can negatively interfere with a metal gate process.

In accordance with one or more embodiments, an FTI opening is backfilled with of a dielectric material after metal gate processing. Embodiments may be implemented to provide a process flow with fewer processing operations and/or to reduce a negative impact on metal gate processing. Embodiments may be implemented to ensure an FTI structure has a gate cut around an FTI area. In an embodiment, an anisotropic etch is used to remove the metal gate and fin/ribbon, followed by dielectric fill.

In accordance with one or more embodiments of the present disclosure, addressing issues outlined above, a metal gate cut process is implemented subsequent to completing gate dielectric and work function metal deposition and patterning. Advantages for implementing approaches described herein can include a so-called “plug-last” approach with a result that a gate dielectric layer (such as a high-k gate dielectric layer) is not deposited on a gate cut plug sidewall, effectively saving additional room for work function metal deposition. By contrast, a metal gate fill material can pinch between the plug and fin during a so-called conventional “plug-first” approach. The space for metal fill can be narrower due to plug mis-registration in the latter approach, and can result in voids during metal fill. In embodiments described herein, using a “plug-last” approach, a work function metal deposition can be seamless (e.g., void free).

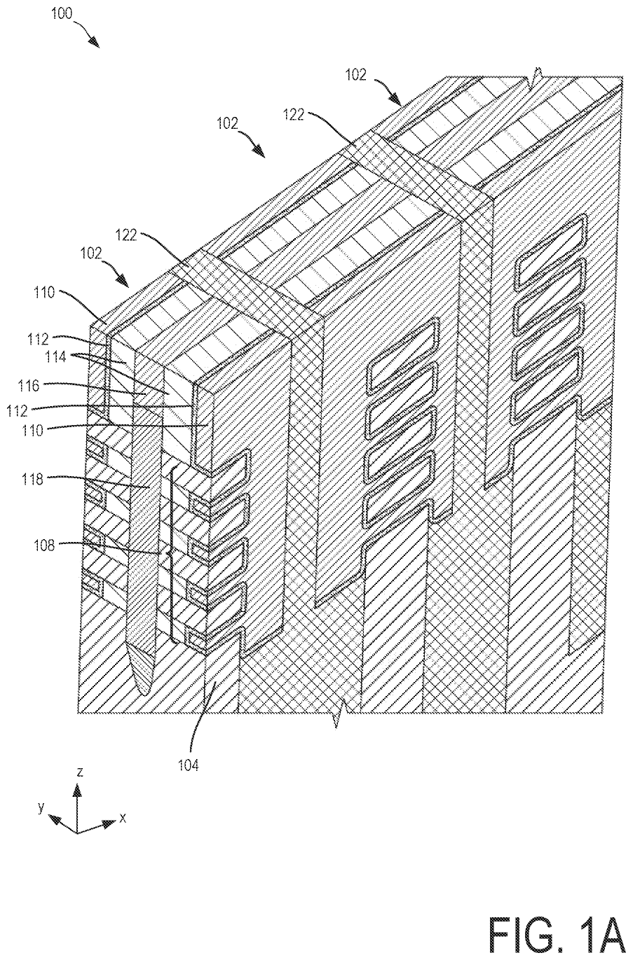

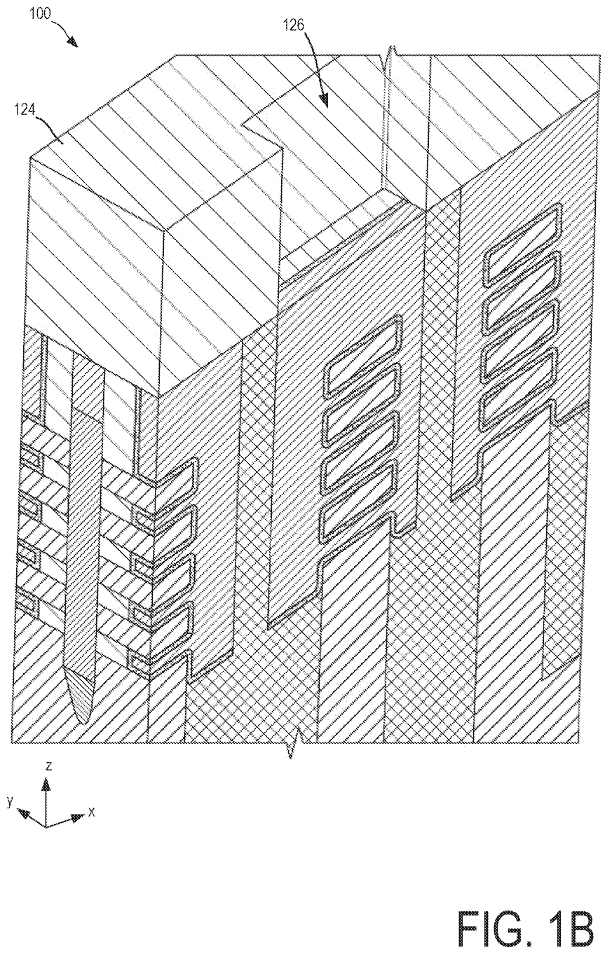

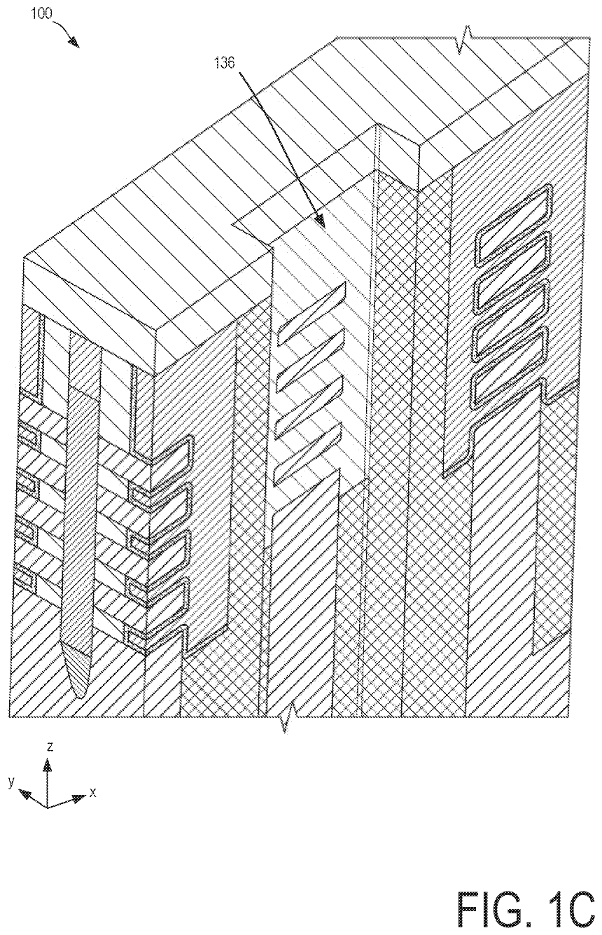

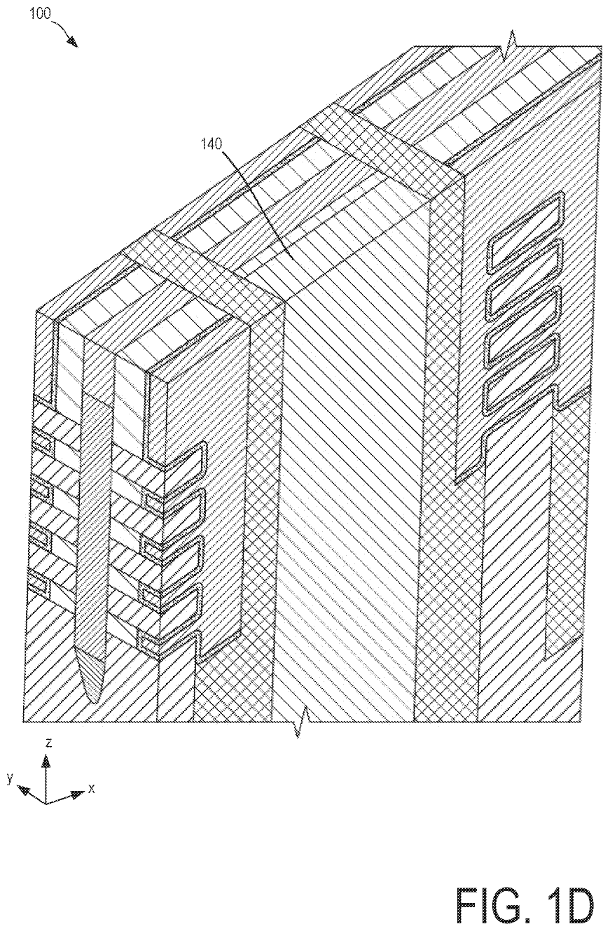

FIGS. 1A-1D illustrate a perspective view of an example process for fabricating nanowire transistor structures with isolation regions in accordance with embodiments herein. Each illustration may represent a particular moment in a method of fabricating with multiple operations, as will be described further below. Although the example shown includes transistor devices with stacks of nanowires (which can also be referred to as nanoribbons or nanosheets in certain instances), aspects of the present disclosure may be applied to other types of transistor structures, e.g., FinFET devices. In addition, aspects of the present disclosure can be applied to other types of processes, e.g., fabricating a semiconductor fin over a sub-fin to replace a stack of nanowires over a sub-fin.

FIG. 1A illustrates an example transistor structure 100 that includes a plurality of transistor device regions 102 before the isolation region fabrication process begins. As shown, the transistor devices 102 of the structure 100 are substantially arranged in a grid pattern, with the devices occupying respective positions in the grid pattern. The devices in each of the x- and y-dimensions of the example being evenly spaced apart from one another. In other words, the gate stacks or gate structures of each device are substantially a first distance apart from one another in the x-dimension, and the gate stacks/gate structures of each device are substantially a second distance apart from one another in the y-dimension. The first and second distances may be the same or may be different. Further, as shown, in the starting form of the structure shown in FIG. 1A, the stack of nanowires 108 are connected with one another in the y-dimension (via the epitaxial source/drain regions 118).

Each transistor device 102 includes sub-fins 104 that extend from a substrate, e.g., silicon sub-fins extending from a silicon substrate. The sub-fins 104 may protrude through a shallow trench isolation (STI) structure, such as a silicon oxide structure. In addition, each transistor device 102 includes a set of nanowires 108 above corresponding ones of the sub-fins 104. Each set of nanowires 108 may be referred to as a stack of nanowires or as a vertical arrangement of horizontally stacked nanowires. Each transistor device 102 further includes a gate stack 110/112 (which can also be referred to as a gate structure) that includes a gate dielectric layer 112 and gate electrode material 110 surrounding the stack of nanowires 108 as shown. The layer 112 may include high-k gate dielectric material, such as Hafnium Oxide or other suitable materials, and the gate electrode 110 may include a conductive material, e.g., Tungsten, Cobalt, or Ruthenium, and in some embodiments, may be implemented as one or more conductive workfunction layers and a conductive fill material. The transistor devices 102 further include epitaxial source/drain regions 118 between sets of nanowires 108 of transistor devices as shown, with conductive contacts 116 above (and in contact with) the regions 118. The epitaxial source/drain regions 118 may include Silicon, Silicon-Germanium (SiGe), or other suitable semiconductor materials, and the contacts 116 may include any suitable conductive material.

Each transistor device 102 is separated by a dielectric spacer 114 (which can also be referred to as “gate cuts” or “gate spacers” in certain instances). The spacers 114 may include Silicon Nitride or other suitable materials. As shown, the dielectric spacers 114 are arranged along sides of the gate stack 110/112, between the gate stack 110/112 and the source/drain regions 118 and contacts 116. In addition to the spacers 114, the structure 100 includes dielectric gate cut plug regions 122 separating different transistor devices 102 of the structure 100. The gate cut plug regions 122 may include, for example, Silicon Oxide (SiO₂), Silicon Nitride (SiN), Silicon Oxynitride (SiON), Silicon Oxycarbide (SiOC), or Aluminum (I) Oxide (Al₂O). The starting structure 100 shown in FIG. 1A may represent a structure after trench contact formation, replacement gate to form a permanent gate stack 110/112, and gate cut and gate cut plug formation which, in this case, is a gate cut last example.

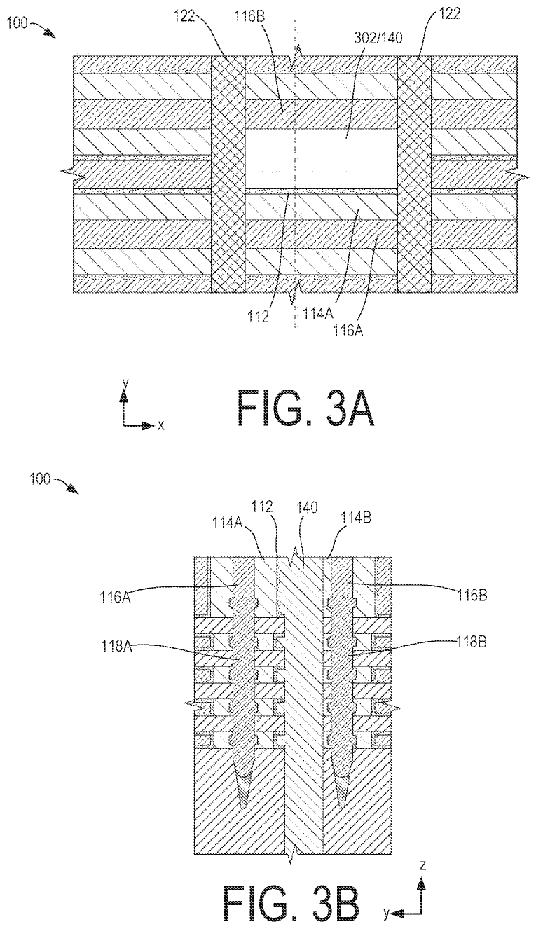

FIG. 1B illustrates the structure 100 with a photoresist layer 124 formed thereon (i.e., formed on the structure shown in FIG. 1A). The photoresist layer 124 is formed to have an opening 126 therein, which provides an opening to a location where a fin trim isolation process is to be performed. The fin trim isolation process may include anisotropic etching to remove the gate stack and nanowires under the opening 126 and/or other openings within the photoresist layer 124. In some instances, there may be a misalignment of the opening 126, which can cause portions of the gate electrode 110 or the gate dielectric layer 112 to remain after the anisotropic etching. Thus, in some embodiments, an additional etching or another processing step (e.g., a selective removal etch or other process) can be performed to remove any remaining portions of the gate electrode 110. In some cases, this may still leave some of the gate dielectric layer 112 in the structure as shown in FIG. 3B.

FIG. 1C illustrates the structure 100 after the anisotropic etching has been performed. As shown, the etching causes a vertical cavity 136 to be formed in the structure 100 based on the location of the opening 126 in the photoresist layer 124. Then, as shown in FIG. 1D, the cavity 136 is filled with a dielectric material to form an isolation region 140. The dielectric material of the isolation region 140 may include, for example, Silicon Oxide (SiO₂), Silicon Nitride (SiN), Silicon Oxynitride (SiON), Silicon Oxycarbide (SiOC), or Aluminum (I) Oxide (Al₂O).

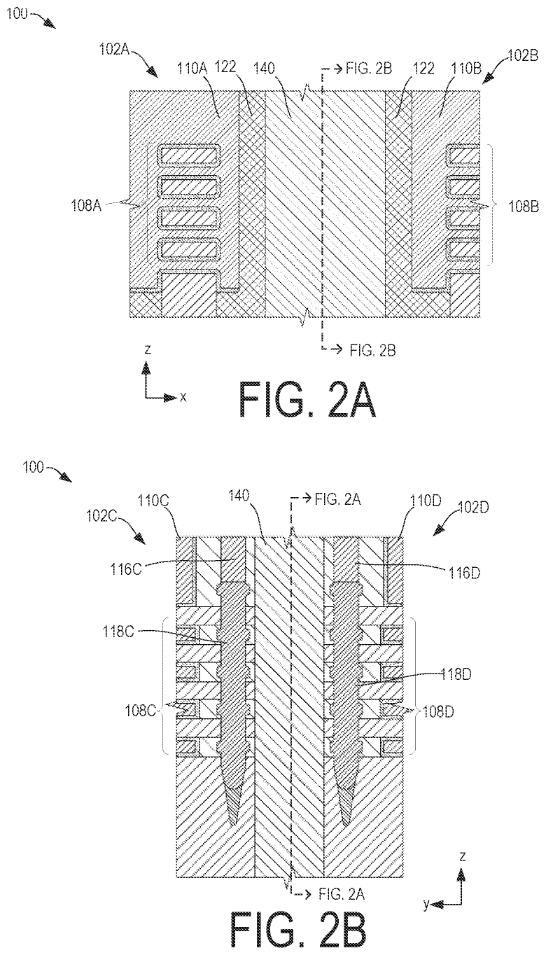

FIGS. 2A-2B illustrate side cross-sectional views of the structure 100 of FIGS. 1A-1D after the isolation region 140 has been formed. As shown, the isolation region 140 is between four different stacked nanowire transistor devices 102A, 102B, 102C, 102D in the structure 100, each having its own respective gate electrode 110, stack of nanowires 108, epitaxial source/drain regions 118 and corresponding contacts 116. As shown in FIG. 2A, there are gate cut plug regions 122 between the gate electrodes 110A, 110B of devices 102A, 120B and the isolation region 140. Further, as shown in FIG. 2B, the isolation region 140 cuts through the nanowire channels 108 of the devices 102C, 102D, isolating the channels/devices from each other. Since the devices 102 are arranged in a grid pattern within the structure 100, the first device 102A may be considered to be spaced a particular distance from the region 140 (e.g., center of the gate stack of the device 102A to the center of the region 140) and the second device 102B may be considered to be substantially spaced twice the distance from the first device 102A than the region 140. For example, the distance between the center of the region 140 and the gate stack of the first device 102A and the distance between the center of the region 140 and the gate stack of the second device 102B may be within +/−10% of one another.

FIGS. 3A-3B illustrate the example structure shown in FIGS. 2A-2B in the scenario in which an opening 302 in a photoresist layer is misaligned. FIG. 3A illustrates a top view of the structure 100, while FIG. 3B illustrates a side cross-sectional view (the same view as shown in FIG. 2B). As described above, there may be a misalignment of the opening in the photoresist layer, which can cause portions of gate electrode 110 or the gate dielectric 112 under the opening to remain after the anisotropic etching has been performed. In the example shown, the opening 302 is misaligned in the vertical direction. Due to this misalignment, the isolation region 140 is offset from the location shown in FIGS. 2A-2B, causing some portions of the gate dielectric 112 to remain. In some cases, the opening 302 may be misaligned in other directions as well (e.g., left/right in the top view shown in FIG. 3A), which can cause further portions of the gate dielectric 112 to remain. In embodiments, an additional etching or another processing step (e.g., a selective removal etch or other process) can be performed prior to the isolation region 140 being formed to remove any remaining portions of the gate electrode.

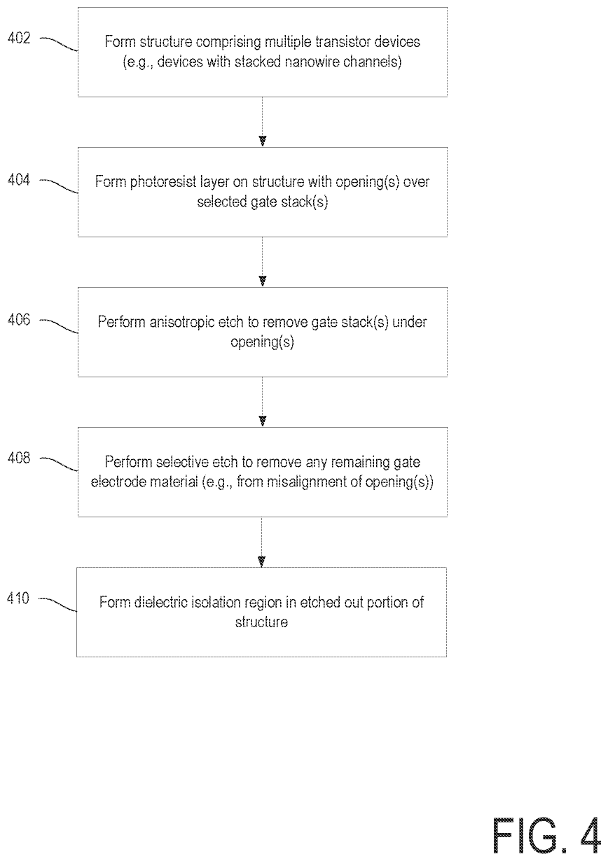

FIG. 4 illustrates a flow diagram of an example process 400 for fabricating isolation regions in a structure comprising multiple transistor devices separated by gate cut plug regions. The example process shown may include additional, fewer, or different operations or aspects than those shown or described below. In some embodiments, one or more of the operations shown may include multiple operations, sub-operations, etc.

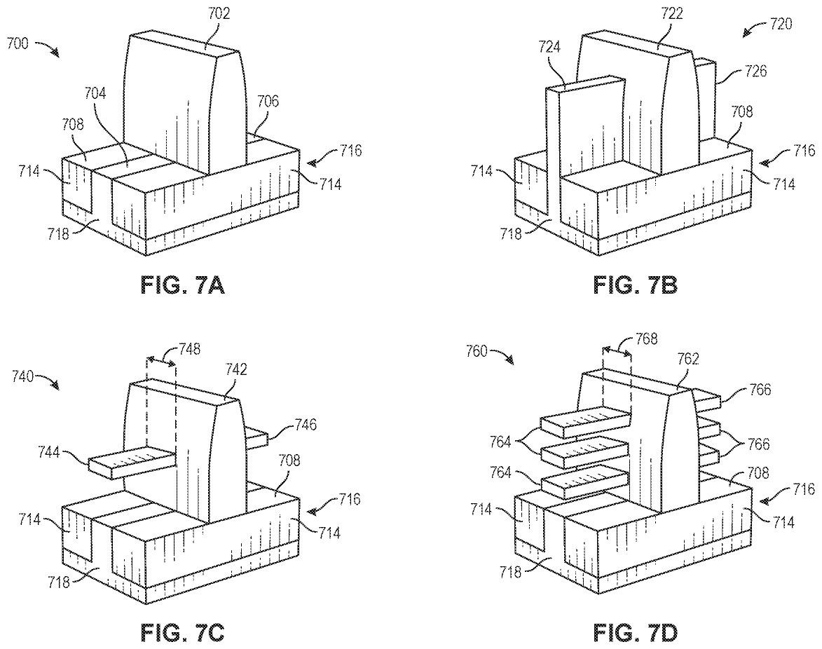

At 402, a structure is formed that includes multiple transistor devices. The structure may be similar to the structure 100 described above with respect to FIGS. 1A-1D, 2A-2B, and 3A-3B. The transistor devices may be stacked nanowire devices such as those shown in FIGS. 1A-1D, 2A-2B, and 3A-3B. In other embodiments, the transistor devices may include a single nanowire, e.g., as shown in FIG. 7C and described below. In still other embodiments, the transistor devices may be FinFET devices, e.g., as shown in FIG. 7B and described below. The structure may include dielectric gate cut plug regions (e.g., 122) separating gate stacks of neighboring transistor devices.

At 404, a photoresist layer (e.g., 124) is formed on the structure, and openings (e.g., 126) are formed in the photoresist layer over selected gate stacks of devices in the structure. At 406, an anisotropic etching process is performed to remove the gate stacks exposed by the openings in the photoresist layer, and at 408, a selective etch is performed to remove any potential remaining gate electrode material in the etched-out gate stacks. Finally, at 410, dielectric isolation regions are formed in the etched-out regions of the structure.

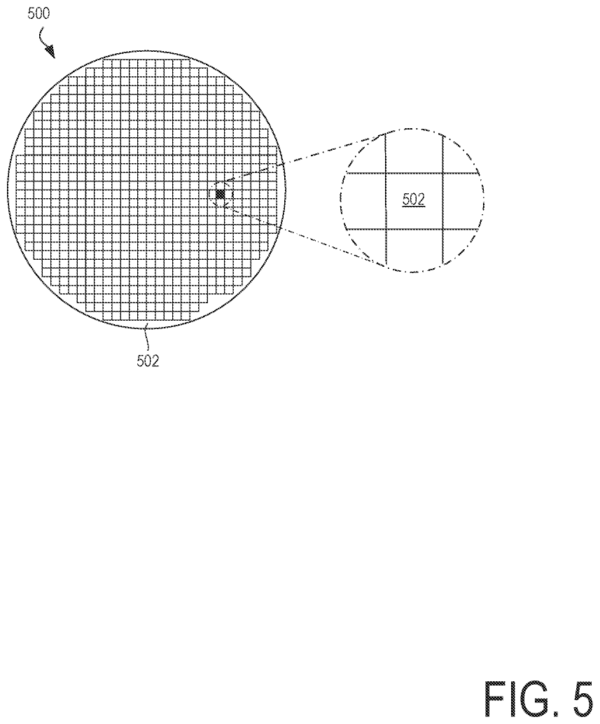

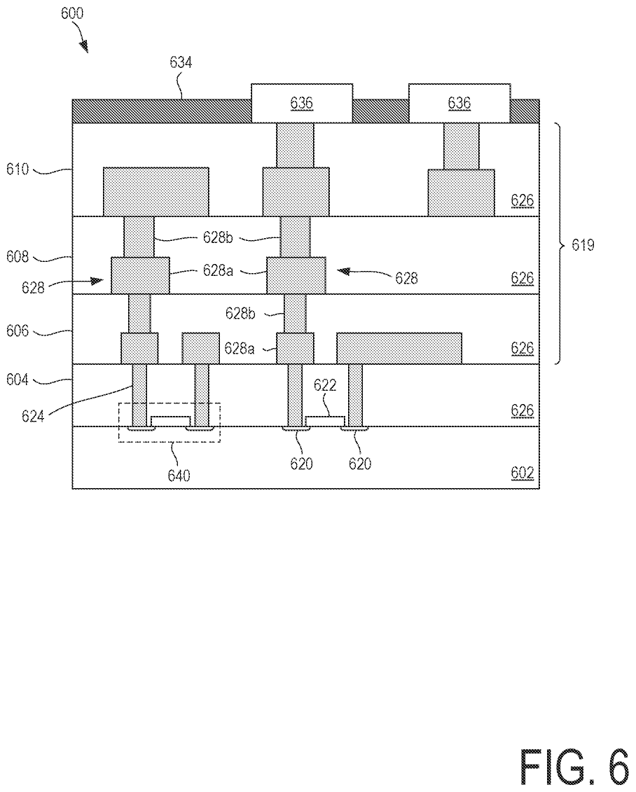

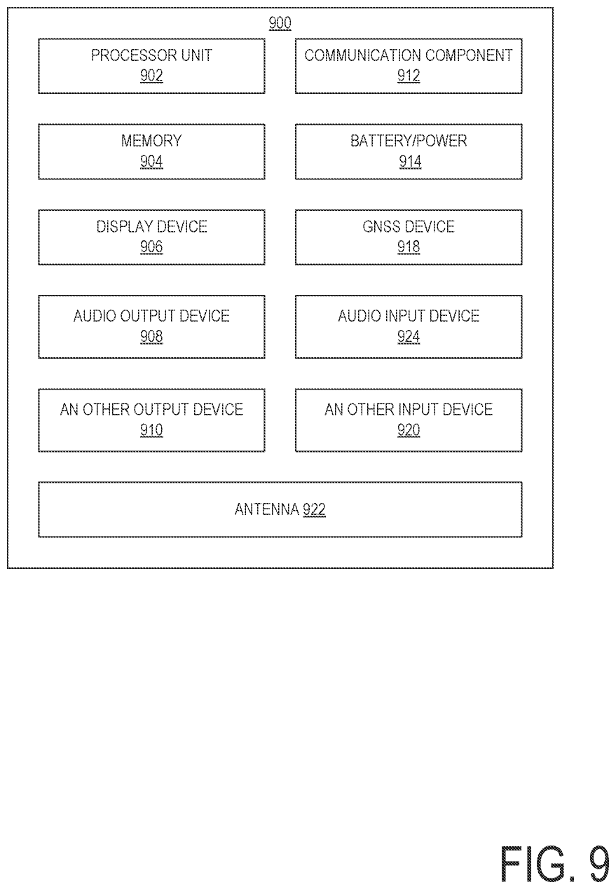

FIG. 5 is a top view of a wafer 500 and dies 502 that may incorporate any of the embodiments disclosed herein. The wafer 500 may be composed of semiconductor material and may include one or more dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The die 502 may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 902 of FIG. 9) or other logic that is configured to store information in the memory devices or execute instructions stored in the memory array.

FIG. 6 is a cross-sectional side view of an integrated circuit device 600 that may be included in any of the embodiments disclosed herein. One or more of the integrated circuit devices 600 may be included in one or more dies 502 (FIG. 5). The integrated circuit device 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit device 600 may be used. The die substrate 602 may be part of a singulated die (e.g., the dies 502 of FIG. 5) or a wafer (e.g., the wafer 500 of FIG. 5).

The integrated circuit device 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

FIGS. 7A-D are simplified perspective views of example planar, FinFET, gate-all-around, and stacked gate-all-around transistors that may be included in any of the embodiments disclosed herein (e.g., in any of the dies). The transistors illustrated in FIGS. 7A-7D are formed on a substrate 716 having a surface 708. Isolation regions 714 separate the source and drain regions of the transistors from other transistors and from a bulk region 718 of the substrate 716.

FIG. 7A is a perspective view of an example planar transistor 700 comprising a gate 702 that controls current flow between a source region 704 and a drain region 706. The transistor 700 is planar in that the source region 704 and the drain region 706 are planar with respect to the substrate surface 708.

FIG. 7B is a perspective view of an example FinFET transistor 720 comprising a gate 722 that controls current flow between a source region 724 and a drain region 726. The transistor 720 is non-planar in that the source region 724 and the drain region 726 comprise “fins” that extend upwards from the substrate surface 728. As the gate 722 encompasses three sides of the semiconductor fin that extends from the source region 724 to the drain region 726, the transistor 720 can be considered a tri-gate transistor. FIG. 7B illustrates one S/D fin extending through the gate 722, but multiple S/D fins can extend through the gate of a FinFET transistor.

FIG. 7C is a perspective view of a gate-all-around (GAA) transistor 740 comprising a gate 742 that controls current flow between a source region 744 and a drain region 746. The transistor 740 is non-planar in that the source region 744 and the drain region 746 are elevated from the substrate surface 728.

FIG. 7D is a perspective view of a GAA transistor 760 comprising a gate 762 that controls current flow between multiple elevated source regions 764 and multiple elevated drain regions 766. The transistor 760 is a stacked GAA transistor as the gate controls the flow of current between multiple elevated S/D regions stacked on top of each other. The transistors 740 and 760 are considered gate-all-around transistors as the gates encompass all sides of the semiconductor portions that extends from the source regions to the drain regions. The transistors 740 and 760 can alternatively be referred to as nanowire, nanosheet, or nanoribbon transistors depending on the width (e.g., widths 748 and 768 of transistors 740 and 760, respectively) of the semiconductor portions extending through the gate.

Returning to FIG. 6, a transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit device 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit devices having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit device 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit device 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit device 600 with another component (e.g., a printed circuit board). The integrated circuit device 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit device 600 is a double-sided die, the integrated circuit device 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit device 600 from the conductive contacts 636.

In other embodiments in which the integrated circuit device 600 is a double-sided die, the integrated circuit device 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit device 600 from the conductive contacts 636. In some embodiments, TSVs extending through the substrate can be used for routing power and ground signals from conductive contacts on the opposite side of the integrated circuit device 600 from the conductive contacts 636 to the transistors 640 and any other components integrated into the die 600, and the metallization stack 619 can be used to route I/O signals from the conductive contacts 636 to transistors 640 and any other components integrated into the die 600.

Multiple integrated circuit devices 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

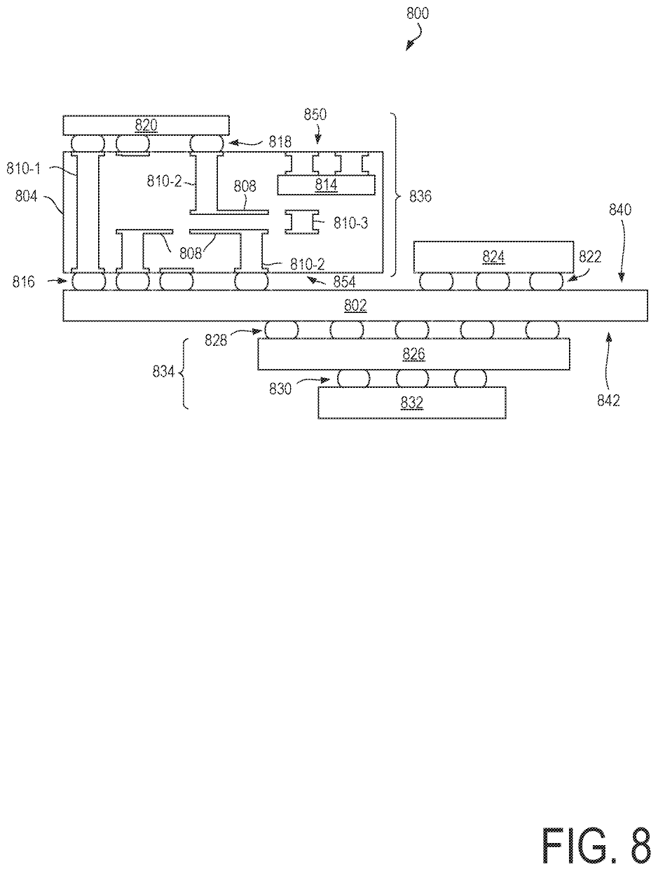

FIG. 8 is a cross-sectional side view of an integrated circuit device assembly 800 that may include any of the embodiments disclosed herein. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpacked integrated circuit product that includes one or more integrated circuit dies (e.g., the die 502 of FIG. 5, the integrated circuit device 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

FIG. 9 is a block diagram of an example electrical device 900 that may include one or more of the embodiments disclosed herein. For example, any suitable ones of the components of the electrical device 900 may include one or more of the integrated circuit device assemblies 800, integrated circuit components 820, integrated circuit devices 600, or integrated circuit dies 502 disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include an other output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an integrated circuit structure comprising: a first transistor device comprising a first gate stack; a second transistor device spaced a first distance laterally from the first transistor device, the second transistor device comprising a second gate stack; a dielectric region between the first gate stack and the second gate stack, the dielectric region spaced a second distance laterally from the first transistor device, the first distance being substantially twice the second distance (e.g., a distance between a center of the first gate stack and a center of the dielectric region is approximately the same (e.g., +/−10%) as a distance between a center of the second gate stack and the center of the dielectric region).

Example 2 includes the subject matter of Example 1, wherein the structure comprises a plurality of transistor devices substantially arranged in a grid, each of the first transistor device, the second transistor device, and the dielectric region each being in a respective grid position.

Example 3 includes the subject matter of Example 1 or 2, wherein the dielectric region is a first dielectric region, and the structure further comprises a second dielectric region between the first dielectric region and the first gate stack and a third dielectric region between the first dielectric region and the second gate stack.

Example 4 includes the subject matter of any one of Examples 1-3, further comprising: a third transistor device comprising a third gate stack, the third transistor device spaced a third distance from the first transistor device in a direction orthogonal to the second transistor device; and an epitaxial source/drain region between the first gate stack and the third gate stack.

Example 5 includes the subject matter of any one of Examples 1-4, wherein the dielectric region is a first dielectric region, and the structure further comprises a second dielectric region adjacent the first dielectric region in a direction orthogonal to the second transistor device.

Example 6 includes the subject matter of any one of Examples 1-5, wherein the first transistor device and the second transistor device are gate all-around (GAA) devices.

Example 7 includes the subject matter of Example 6, wherein the first transistor device and the second transistor device comprise a plurality of vertically stacked nanowires surrounded by a gate electrode region.

Example 8 includes the subject matter of any one of Examples 1-5, wherein the first transistor device and the second transistor device are FinFET devices.

Example 9 is an integrated circuit structure comprising: a plurality of transistor devices substantially arranged in a grid pattern, the plurality of transistor devices comprising: a first transistor device in a first position of the grid pattern, the first transistor device comprising a gate electrode material surrounding one or more channels and a dielectric material between the one or more channels and the gate electrode material; a second transistor device in a second position of the grid pattern, the second transistor device comprising a gate electrode material surrounding one or more channels and a dielectric material between the one or more channels and the gate electrode material; and a dielectric region in a third position of the grid pattern between the first transistor device and the second transistor device.

Example 10 includes the subject matter of Example 9, wherein the dielectric region is a first dielectric region and the structure further comprises: a second dielectric region between the first transistor device and the first dielectric region, the second dielectric region in contact with the gate electrode material of the first transistor device and with the first dielectric region; and a third dielectric region between the second transistor device and the first dielectric region, the third dielectric region in contact with the gate electrode material of the second transistor device and with the first dielectric region.

Example 11 includes the subject matter of any one of Examples 9-10, wherein the first transistor device and the second transistor device are spaced in a first direction of the grid pattern, and the structure further comprises a third transistor device in a fourth position of the grid pattern, the third transistor spaced in a second direction from the dielectric region orthogonal to the first direction.

Example 12 includes the subject matter of Example 11, wherein the dielectric region is a first dielectric region and the structure further comprises a second dielectric region adjacent the first dielectric region in the second direction.

Example 13 includes the subject matter of any one of Examples 9-12, wherein the first transistor device and the second transistor device comprise a nanowire channel surrounded by gate electrode material.

Example 14 includes the subject matter of any one of Examples 9-12, wherein the first transistor device and the second transistor device comprise a plurality of vertically stacked nanowire channels surrounded by gate electrode material.

Example 15 includes the subject matter of any one of Examples 9-12, wherein the first transistor device and the second transistor device comprise a fin-shaped channel surrounded by gate electrode material.

Example 16 is a method comprising: forming a structure comprising a plurality of transistor devices arranged substantially in a grid pattern; forming a photoresist layer over the structure; forming an opening in the photoresist layer over a gate stack of a transistor device of the structure; performing an anisotropic etch to remove the gate stack under the opening; and forming a dielectric region in a portion of the structure removed by the anisotropic etch.

Example 17 includes the subject matter of Example 16, further comprising performing a selective etch before forming the dielectric region, the selective etch to remove gate electrode material of the gate stack.

Example 17 includes the subject matter of any one of Examples 16-17, wherein the transistor devices are gate all-around (GAA) devices.

Example 17 includes the subject matter of Example 18, wherein the transistor devices comprise a plurality of vertically stacked nanowires surrounded by a gate electrode region.

Example 17 includes the subject matter of any one of Examples 16-17, wherein the transistor devices are FinFET devices.

Example 21 is a structure formed by the method of any one of Examples 16-20.

Example 22 is an integrated circuit device assembly comprising: an integrated circuit component comprising a structure according to any one of Examples 1-14.

Example 23 includes the integrated circuit device assembly device of Example 22, further comprising a circuit board coupled to the integrated circuit component.

Example 24 is a computing device comprising a processor and memory, the processor comprising the structure according to any one of Examples 1-14.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit structure comprising:
a first transistor device comprising a first gate stack;
a second transistor device spaced a first distance laterally from the first transistor device, the second transistor device comprising a second gate stack;
a dielectric region between the first gate stack and the second gate stack, the dielectric region spaced a second distance laterally from the first transistor device, the first distance being substantially twice the second distance.

2. The integrated circuit structure of claim 1, wherein the structure comprises a plurality of transistor devices substantially arranged in a grid, each of the first transistor device, the second transistor device, and the dielectric region each being in a respective grid position.

3. The integrated circuit structure of claim 1, wherein the dielectric region is a first dielectric region, and the structure further comprises a second dielectric region between the first dielectric region and the first gate stack and a third dielectric region between the first dielectric region and the second gate stack.

4. The integrated circuit structure of claim 1, further comprising:
a third transistor device comprising a third gate stack, the third transistor device spaced a third distance from the first transistor device in a direction orthogonal to the second transistor device; and
an epitaxial source/drain region between the first gate stack and the third gate stack.

5. The integrated circuit structure of claim 1, wherein the dielectric region is a first dielectric region, and the structure further comprises a second dielectric region adjacent the first dielectric region in a direction orthogonal to the second transistor device.

6. The integrated circuit structure of claim 1, wherein the first transistor device and the second transistor device are gate all-around (GAA) devices.

7. The integrated circuit structure of claim 6, wherein the first transistor device and the second transistor device comprise a plurality of vertically stacked nanowires surrounded by a gate electrode region.

8. The integrated circuit structure of claim 1, wherein the first transistor device and the second transistor device are FinFET devices.

9. An integrated circuit structure comprising:
a plurality of transistor devices substantially arranged in a grid pattern, the plurality of transistor devices comprising:
a first transistor device in a first position of the grid pattern, the first transistor device comprising a gate electrode material surrounding one or more channels and a dielectric material between the one or more channels and the gate electrode material;
a second transistor device in a second position of the grid pattern, the second transistor device comprising a gate electrode material surrounding one or more channels and a dielectric material between the one or more channels and the gate electrode material; and
a dielectric region in a third position of the grid pattern between the first transistor device and the second transistor device.

10. The integrated circuit structure of claim 9, wherein the dielectric region is a first dielectric region and the structure further comprises:
a second dielectric region between the first transistor device and the first dielectric region, the second dielectric region in contact with the gate electrode material of the first transistor device and with the first dielectric region; and
a third dielectric region between the second transistor device and the first dielectric region, the third dielectric region in contact with the gate electrode material of the second transistor device and with the first dielectric region.

11. The integrated circuit structure of claim 9, wherein the first transistor device and the second transistor device are spaced in a first direction of the grid pattern, and the structure further comprises a third transistor device in a fourth position of the grid pattern, the third transistor spaced in a second direction from the dielectric region orthogonal to the first direction.

12. The integrated circuit structure of claim 11, wherein the dielectric region is a first dielectric region and the structure further comprises a second dielectric region adjacent the first dielectric region in the second direction.

13. The integrated circuit structure of claim 9, wherein the first transistor device and the second transistor device comprise a nanowire channel surrounded by gate electrode material.

14. The integrated circuit structure of claim 9, wherein the first transistor device and the second transistor device comprise a plurality of vertically stacked nanowire channels surrounded by gate electrode material.

15. The integrated circuit structure of claim 9, wherein the first transistor device and the second transistor device comprise a fin-shaped channel surrounded by gate electrode material.

16. A method comprising:
forming a structure comprising a plurality of transistor devices arranged substantially in a grid pattern;
forming a photoresist layer over the structure;
forming an opening in the photoresist layer over a gate stack of a transistor device of the structure;
performing an anisotropic etch to remove the gate stack under the opening; and
forming a dielectric region in a portion of the structure removed by the anisotropic etch.

17. The method of claim 16, further comprising performing a selective etch before forming the dielectric region, the selective etch to remove gate electrode material of the gate stack.

18. The method of claim 16, wherein the transistor devices are gate all-around (GAA) devices.

19. The method of claim 18, wherein the transistor devices comprise a plurality of vertically stacked nanowires surrounded by a gate electrode region.

20. The method of claim 16, wherein the transistor devices are FinFET devices.
